(19) United States
(12) Patent Application Publication
(10) Pub. No.: US 2025/0275442 A1
(43) Pub. Date: Aug. 28, 2025

(54) LIGHT EMITTING DISPLAY APPARATUS

(71) Applicant: LG Display Co., Ltd., Seoul (KR)

(72) Inventors: HeeJung Yang, Paju-si (KR); YoungWook Lee, Paju-si (KR); SeungHee Nam, Paju-si (KR); Jungmin Kim, Paju-si (KR); Hoseung Lee, Paju-si (KR)

(73) Assignee: LG Display Co., Ltd., Seoul (KR)

(21) Appl. No.: 18/982,836

(22) Filed: Dec. 16, 2024

(30) Foreign Application Priority Data
Feb. 23, 2024 (KR) 10-2024-0026507

(51) Int. Cl. H10K 59/80; H10K 59/122

(52) U.S. Cl. CPC H10K 59/879; H10K 59/122; H10K 59/8792

(57) ABSTRACT

A light emitting display apparatus may include: a substrate comprising a plurality of pixels having a plurality of sub-pixels; a light extraction portion disposed on the substrate and located in each of the plurality of sub-pixels; a flat portion connected to the light extraction portion and surrounding the light extraction portion; a bank spaced apart from the light extraction portion and disposed on the flat portion; a first electrode disposed on the light extraction portion and the flat portion and partially covered by the bank; an organic light emitting layer disposed on the first electrode and the bank; and a light blocking portion disposed in at least a portion between the organic light emitting layer and the first electrode.

### CROSS-REFERENCE TO RELATED APPLICATIONS

This application claims the benefit of Korean Patent Applications No. 10-2024-0026507, filed on Feb. 23, 2024, which are hereby incorporated by reference as if fully set forth herein.

### BACKGROUND

### Field

The present disclosure relates to a light emitting display apparatus.

### Discussion of the Related Art

A light emitting display apparatus has a high response speed and has low power consumption. Unlike a liquid crystal display apparatus, the light emitting display apparatus is a self-emissive display apparatus and does not require a separate light source. Thus, the light emitting display apparatus is subject to a next generation flat panel display apparatus.

The light emitting display apparatus displays an image through light emission of an emitting device layer including an emission layer interposed between two electrodes.

The light emitting display apparatus has a lens-shaped anode electrode to increase the light extraction efficiency, but there is a problem that the cathode electrode is formed thinly due to a high taper angle of the inclined surface of a bank covering an edge of the lens-shaped anode electrode, and that the cathode electrode is easily disconnected (or broken) by an external force. Accordingly, in the light emitting display apparatus, the inclined surface of the bank is disposed on a flat anode electrode connected to a lens-shaped anode electrode, but there is a problem that an abnormal color defect occurs due to the thickness difference (or optical distance difference) between the light emitting layer on the flat anode electrode and the light emitting layer on the lens-shaped anode electrode.

### SUMMARY

Accordingly, the present disclosure is directed to a light emitting display apparatus that substantially obviates one or more of the problems due to limitations and disadvantages of the related art.

An aspect of the present disclosure is directed to providing a light emitting display apparatus in which an abnormal color defect may be prevented.

Further, an aspect of the present disclosure is directed to providing a light emitting display apparatus in which the light extraction efficiency of light emitted from a light emitting element layer may be improved through preventing color abnormality defects.

Further, an aspect of the present disclosure is directed to providing a light emitting display apparatus in which overall power consumption may be reduced through light extraction.

The objects of the present disclosure are not limited to the above-described objects, and other objects not mentioned can be clearly understood by those skilled in the art from the following description.

To achieve these objects and other advantages of the present disclosure, as embodied and broadly described herein, a light emitting display apparatus according to an embodiment of the present disclosure may include: a substrate comprising a plurality of pixels having a plurality of sub-pixels; a light extraction portion disposed on the substrate and located in each of the plurality of sub-pixels; a flat portion connected to the light extraction portion and surrounding the light extraction portion; a bank spaced apart from the light extraction portion and disposed on the flat portion; a first electrode disposed on the light extraction portion and the flat portion and partially covered by the bank; an organic light emitting layer disposed on the first electrode and the bank; and a light blocking portion disposed in at least a portion between the organic light emitting layer and the first electrode.

Additional features and aspects of the disclosure will be set forth in the description that follows and in part will become apparent from the description or may be learned by practice of the inventive concepts provided herein. Other features and aspects of the inventive concepts may be realized and attained by the structure particularly pointed out in, or derivable from, the written description, claims hereof, and the appended drawings.

It is to be understood that both the foregoing general description and the following detailed description of the present disclosure are by way of example and are intended to provide further explanation of the disclosures as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principles of the disclosure.

FIG. 1 is a schematic plan view of a light emitting display apparatus according to an example embodiment of the present disclosure.

FIG. 2 is a schematic plan view of a single example pixel illustrated in FIG. 1.

FIG. 3 is an example schematic cross-sectional view of the line I-I′ shown in FIG. 2.

FIG. 4 is an example schematic cross-sectional view of the line II-II′ shown in FIG. 2.

FIG. 5 is an example schematic enlarged cross-sectional view of portion A shown in FIG. 3.

FIG. 6 is a graph illustrating the light transmittance of a light blocking portion with respect to the thickness of a light blocking portion of the light emitting display apparatus according to an example embodiment of the present disclosure.

FIG. 7 is an illustration of a modified example of FIG. 5.

FIG. 8 is a graph illustrating the color coordinates of a light emitting display apparatus according to an example embodiment of the present disclosure compared to a light emitting display apparatus according to a modified example and a comparison example.

FIG. 9 is a schematic cross-sectional view of a light emitting display apparatus according to another example embodiment of the present disclosure.

FIG. 10 is a schematic enlarged cross-sectional view of portion B shown in FIG. 9.

FIG. 11 is an illustration of a modified example of FIG. 10.

### DETAILED DESCRIPTION

Reference will now be made in detail to the embodiments of the present disclosure, examples of which are illustrated in the accompanying drawings. Wherever possible, the same reference numbers will be used throughout the drawings to refer to the same or like parts.

Advantages and features of the present disclosure and methods of achieving them will become apparent with reference to the example embodiments described below in detail in conjunction with the accompanying drawings. The present disclosure may, however, be embodied in different forms and should not be construed as limited to the example embodiments set forth herein. Rather, these example embodiments are provided so that this disclosure will be thorough and complete and will fully convey the scope of the present disclosure to those skilled in the art.

The shapes, dimensions, areas, lengths, thicknesses, ratios, angles, numbers, and the like, which are illustrated in the drawings to describe various example embodiments of the present disclosure, are merely given by way of example. Therefore, the present disclosure is not limited to such illustrated details in the drawings. Like reference numerals generally denote like elements throughout the specification, unless otherwise specified.

In the following description, where a detailed description of a relevant known function or configuration may unnecessarily obscure aspects of the present disclosure, a detailed description of such a known function or configuration may be omitted or be briefly discussed.

Where a term like “comprise,” “have,” or “include” is used, one or more other elements may be added unless the term is used with a more limiting term, such as “only” or the like. An element described in a singular form may include a plurality of elements, and vice versa, unless the context clearly indicates otherwise.

In construing an element, the element should be construed as including an error or tolerance range even where no explicit description of such an error or tolerance range is provided.

Where a positional relationship between two elements is described with such a term as “on,” “over,” “under,” “next to,” or the like, one or more other elements may be located between the two elements unless the term is used with a more limiting term, such as “immediate(ly)” or “direct(ly).”

Where a temporal relationship is described using such a term as “after,” “subsequent(ly),” “next,” “before,” or the like, it may include a non-consecutive or non-continuous case unless it is used with a more limiting term like “immediately” or “directly.”

Although terms “first,” “second,” and the like may be used herein to describe various elements, these elements should not be interpreted to be limited by these terms as they are not used to define a particular essence, order, sequence, precedence, or number of such elements. These terms are used only to refer one element separately from another. For example, a first element could be termed a second element, and a second element could similarly be termed a first element, without departing from the scope of the present disclosure.

Terms like “X-axis direction”, “Y-axis direction,” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure may be partially or wholly coupled to or combined with each other, and may be operated, linked, or driven together in various ways as those skilled in the art can sufficiently understand. The embodiments of the present disclosure may be carried out independently from each other, or may be carried out together in association with each other.

Hereinafter, example embodiments of the present disclosure will be described in detail with reference to the accompanying drawings.

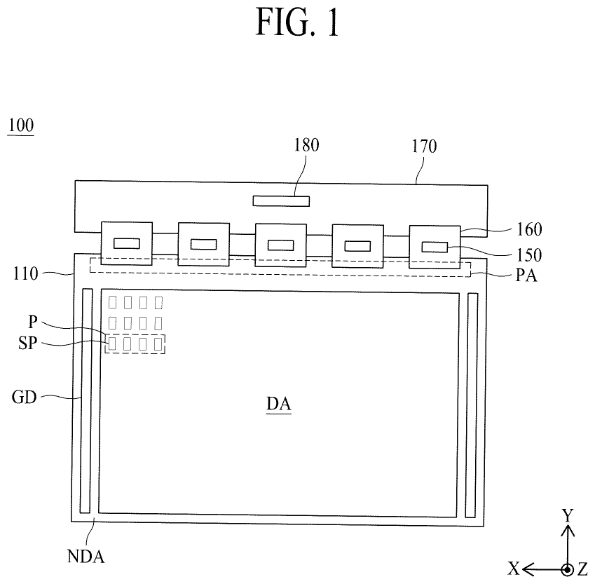

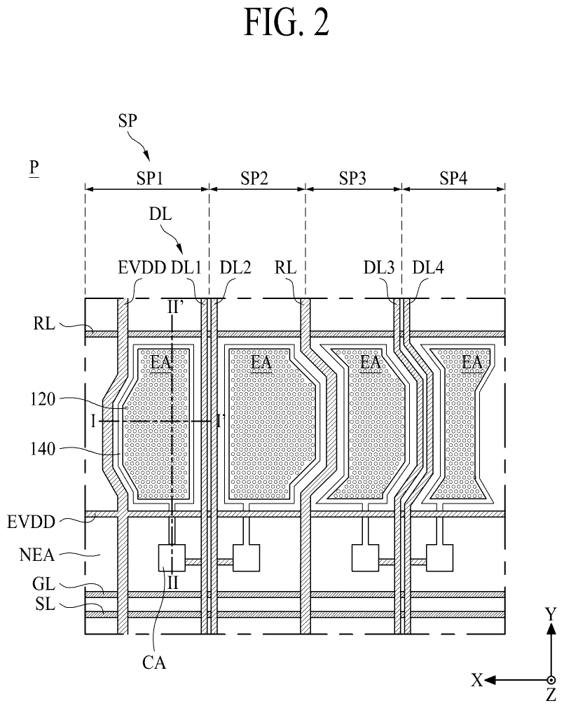

FIG. 1 is a schematic plan view of a light emitting display apparatus according to an example embodiment of the present disclosure, and FIG. 2 is a schematic plan view of a single example pixel illustrated in FIG. 1.

Hereinafter, a first direction (Y-axis direction) indicates a direction parallel to a data line (DL, shown in FIG. 2), a second direction (X-axis direction) indicates a direction parallel to a gate line (GL, shown in FIG. 2), and a third direction (Z-axis direction) indicates the thickness direction of the light emitting display apparatus 100.

As shown in FIG. 1, the display apparatus 100 according to an example embodiment of the present disclosure may include a display panel having a gate driver GD, a source drive integrated circuit (hereinafter, referred to as “IC”) 150, a flexible film 160, a circuit board 170, and a timing controller 180.

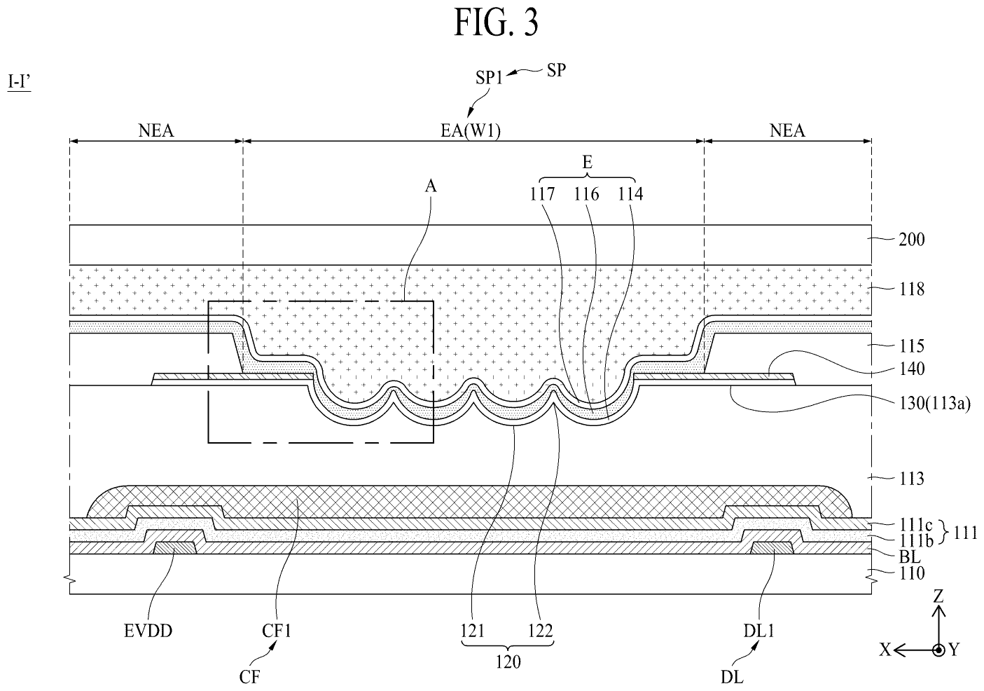

The display panel may include a substrate 110 and an opposite substrate 200 (shown in FIG. 3).

The substrate 110 may include a thin film transistor, and may be a transistor array substrate, a lower substrate, a base substrate, or a first substrate. The substrate 110 may be a transparent glass substrate or a transparent plastic substrate.

The opposite substrate 200 may be oppositely bonded to the substrate 110 via an adhesive member. For example, the opposite substrate 200 may have a smaller size than the substrate 110 and may be oppositely bonded to a portion of the substrate 110 other than the pad portion. The opposite substrate 200 may be a top substrate, a second substrate, or an envelope substrate. Hereinafter, the opposite substrate 200 is defined as a second substrate.

The gate driver GD supplies gate signals to the gate lines in accordance with the gate control signal input from the timing controller 180. When the source drive IC 150 is manufactured as a driving chip, the source drive IC 150 may be packaged in the flexible film 160 in a chip on film (COF) method or a chip on plastic (COP) method.

Pads, such as power pads, data pads, may be formed in the non-display area of the display panel. Lines connecting the pads with the source drive IC 150 and lines connecting the pads with lines of the circuit board 170 may be formed in the flexible film 160. The flexible film 160 may be attached onto the pads by using an anisotropic conducting film, whereby the pads may be connected with the lines of the flexible film 160.

As shown in FIG. 1, the substrate 110 according to an example may include a display area DA and a non-display area NDA.

The display area DA is an area where an image is displayed, and may be a pixel array area, an active area, a pixel array unit, a display unit, or a screen. For example, the display area DA may be disposed at a central portion of the display panel.

The display area DA according to an example may include gate lines, data lines, pixel driving power lines, and a plurality of pixels P. Each of the plurality of pixels P may include a plurality of subpixels SP that may be defined by the gate lines and the data lines. Each of the plurality of sub-pixels SPs may be defined as an area of the smallest unit in which actual light is emitted.

As shown in FIG. 2, at least four of the plurality of sub-pixels SPs provided to emit different colors and disposed adjacent to each other comprise one unit pixel P. The one unit pixel may include, but is not limited to, a red sub-pixel, a green sub-pixel, a blue sub-pixel, and a white sub-pixel. According to another example, three sub-pixels SPs of the plurality of sub-pixels SPs provided to emit different colors and disposed adjacent to each other constitute one unit pixel. The one unit pixel may include, but is not limited to, at least one red sub-pixel, at least one green sub-pixel, at least one blue sub-pixel, and at least one white sub-pixel.

Each of the plurality of sub-pixels SPs may include a thin film transistor, and a light emitting element connected to the thin film transistor. The sub-pixel may include a light emitting layer (or the organic light emitting layer 116, shown in FIG. 3) disposed between the first electrode 114 and the second electrode 117 (or a cathode electrode 117).

The organic light emitting layers disposed on each of the plurality of sub-pixels SPs may individually emit different colored light or may emit white light in common. According to one example, when the emitting portion of each of the plurality of sub-pixels SPs emits white light in common, each of the red sub-pixel, the green sub-pixel, and the blue sub-pixel may include a color filter (or wavelength conversion member CF) that converts the white light into different color light. In this case, the white sub-pixel according to one example may not comprise a color filter. The color filters CFs according to one example may include a red color filter CF1, a blue color filter, and a green color filter.

In the light emitting display apparatus 100 according to an example embodiment of the present disclosure, the area provided with the red color filter CF1 may be a red sub-pixel SP1, the area provided with the blue color filter may be a blue sub-pixel SP3, the area provided with the green color filter may be a green sub-pixel SP4, and the area without the color filter may be a white sub-pixel SP2. In the present specification, the red sub-pixel SP1 may be represented by a first sub-pixel provided to emit red light, the blue sub-pixel SP3 may be represented by a third sub-pixel provided to emit blue light, the green sub-pixel SP4 may be represented by a fourth sub-pixel provided to emit green light, and the white sub-pixel SP2 may be represented by a second sub-pixel provided to emit white light.

Each of the subpixels SP supplies a predetermined current to the organic light emitting element in accordance with a data voltage of the data line when a gate signal is input from the gate line by using the thin film transistor. For this reason, the light emitting layer of each of the subpixels may emit light with a predetermined brightness in accordance with the predetermined current.

The display area DA includes a light emission area EA and a non-light emission area NEA (shown in FIG. 3). The light emission area EA may be an area from which light is emitted. In one example, the light emission area EA may be an area where the organic light emitting layer 116 between the first electrode 114 and the cathode electrode 117 is emitted due to the formation of an electric field between the first electrode 114 and the cathode electrode 117. The light emission area EA may be a region where light emitted from the organic light emitting layer 116 is emitted to the substrate 110. The non-light emission area NEA may be an area that does not transmit most of the light incident from the outside. For example, the non-light emission area NEA may be an area other than the light emission area EA from which light is emitted. In one example, the non-light emission area NEA may be provided between a plurality of sub-pixels SPs on the substrate 110.

The non-light emission area NEA may be disposed with a plurality of pixels P and a plurality of wiring (or line) for driving each of the plurality of pixels P. The plurality of wiring, according to one example, may include a plurality of first signal lines and a plurality of second signal lines.

The plurality of first signal lines may extend in the second direction (X-axis direction). Each of the plurality of first signal lines may include at least one scan line (or gate line GL) and at least one sensing line SL.

The plurality of second signal lines may extend in the first direction (Y-axis direction). The plurality of second signal lines may intersect with the plurality of first signal lines. Each of the plurality of second signal lines may include a pixel power line EVDD, a plurality of data lines (DL), and a reference line RL. The plurality of data lines DL may include a first data line DL1 for driving the first sub-pixel SP1, a second data line DL2 for driving the second sub-pixel SP2, a third data line DL3 for driving the third sub-pixel SP3, and a fourth data line DL4 for driving the fourth sub-pixel SP4.

Hereinafter, when the second signal line includes a plurality of lines, one second signal line may refer to a signal line group consisting of a plurality of lines. For example, when the second signal line includes four data lines, the pixel power line, and the reference line, one second signal line may refer to a group of signal lines comprising four data lines, the pixel power line, and the reference line.

Referring back to FIG. 1, the non-display area NDA is an area on which an image is not displayed, and may be a peripheral circuit area, a signal supply area, an inactive area or a bezel area. The non-display area NDA may be configured to be in the vicinity of the display area DA. That is, the non-display area NDA may be disposed to surround the display area DA.

The light emitting display apparatus 100 according to an example embodiment of the present disclosure may include a pad portion PA disposed in the non-display area NDA. The pad portion PA may be for driving a plurality of pixels P. For example, the pad portion PA may provide power and/or signals for the plurality of pixels P disposed in the display area DA to output images. In one example, the pad portion PA may be disposed in a non-display area NDA on the top side of the substrate 110 with reference to FIG. 1.

The gate driver GD supplies gate signals to the gate lines according to the gate control signals input from the timing controller 180. The gate driver GD may be formed in a gate driver in panel GIP manner on one side of the display area DA of the display panel or on the non-display area NDA outside both sides of the display area DA, as shown in FIG. 1. Alternatively, the gate driver GD may be made of a driver chip, mounted on a flexible film, and attached to the display panel by tape automated bonding TAB to the non-display area NDA on one side of the display area DA or to the non-display area NDA on both sides of the display area DA.

The plurality of gate drivers GDs may be separately disposed in the non-display area to the left of the display area DA and in the non-display area to the right of the display area DA. According to an example, the plurality of gate drivers GD may be connected to the plurality of pixels P and to the plurality of first signal lines for supplying signals to each of the plurality of pixels P. The plurality of first signal lines may include at least one signal line for supplying signals for driving the pixels P.

The plurality of second signal lines may extend in the first direction (Y-axis direction). The plurality of second signal lines may intersect with the plurality of first signal lines. The plurality of second signal lines may include the pixel power line EVDD and at least one data line for supplying a data voltage to the pixel P. Each of the plurality of second signal lines may be connected to at least one of a plurality of pads, a pixel power shorting bar (not shown), and a common power shorting bar (not shown). The pixel power shorting bars and the common power shorting bars are disposed on the non-display area NDA opposite to the pad portion PA with respect to the display area DA, for example, may be disposed in the non-display area NDA on the bottom side of the substrate 110.

The pixels P are disposed to overlap with at least one of the first signal lines and the second signal line and emit a predetermined light to display an image. The light emission area EA may correspond to an area in which the pixels P emit light.

The non-light emission area NEA may refer to an area provided in the display area DA that does not emit light and may be expressed by the term dead zone because it does not emit light. A dead zone according to one example may be a region provided with banks, but is not limited thereto, and may also refer to a region that does not emit light.

In the non-light emission area NEA, a plurality of wiring may be disposed, for example, a first signal line and a second signal line may be disposed. The first signal lines, according to one example, may include gate lines GL extending in a second direction (X-axis direction). The second signal lines, according to one example, may include the pixel power line EVDD, the reference line RL, and the plurality of data lines DL extending long in the first direction (Y-axis direction).

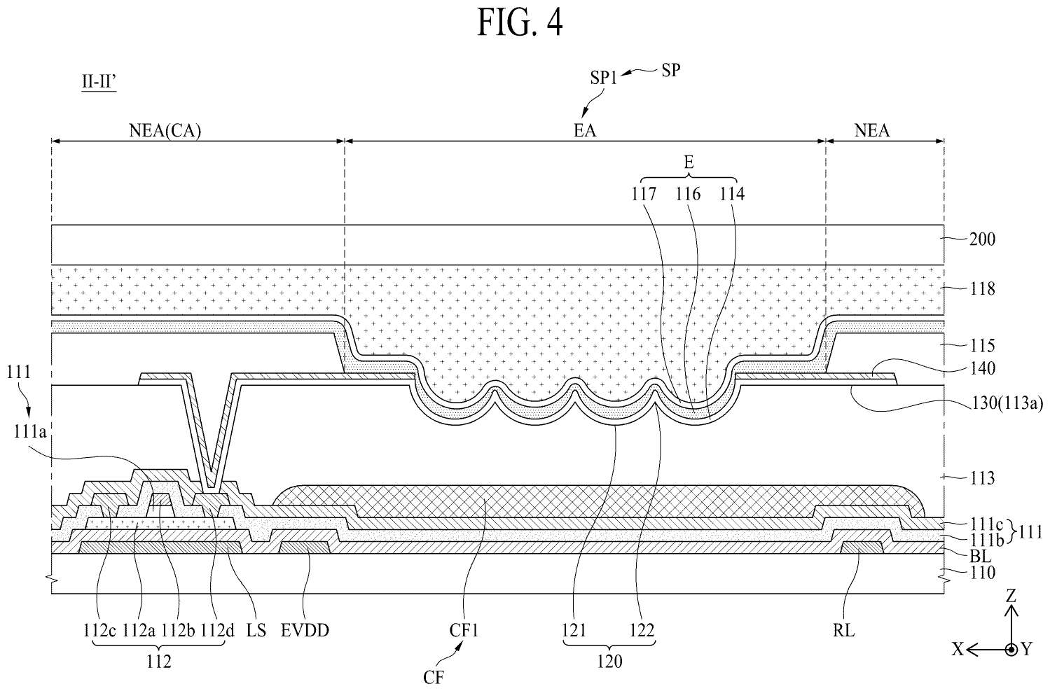

FIG. 3 is a schematic cross-sectional view of the line I-I′ shown in FIG. 2, and FIG. 4 is a schematic cross-sectional view of the line II-II′ shown in FIG. 2.

As shown in FIGS. 3 and 4, the light emitting display apparatus 100 according to an example embodiment of the present disclosure may include a light extraction portion 120 disposed on the substrate 110 and disposed on each of the plurality of sub-pixels SPs. The light extraction portion 120 may be formed on a top side (or upper surface) of the overcoat layer 113 such that it overlaps with the light emission area EA of each of the plurality of sub-pixels SPs. The light extraction portion 120 may be formed at the overcoat layer 113 of the light emission area EA to have a curved shape (or an uneven shape), whereby a progress path of light emitted from the light emitting device layer E is changed to increase light extraction efficiency of the pixel P. For example, the light extraction portion 120 may be referred to as a non-planar portion, an uneven pattern portion, a micro lens, or a light scattering pattern.

The light extraction portion 120 may include a plurality of concave portions 121, and a convex portion 122 (or a plurality of convex portion 122) disposed around each of the plurality of concave portions 121. The plurality of concave portions 121 may be formed or provided to be concave from an upper surface of the overcoat layer 113 in the light emission area EA. The convex portion 122 (or a plurality of convex portion 122) may be disposed between the plurality of concave portions 121. The convex portion 122 (or a plurality of convex portion 122) may be formed to surround each of the plurality of concave portions 121.

A top portion of the convex portion 122 may include a sharp tip structure (or a pointed tip structure) in order to enhance light extraction efficiency of the pixel, but an embodiment according to present disclosure is not limited thereto. For example, the top portion of the convex portion 122 may have a convex curved shape. For example, the top portion of the convex portion 122 may include a dome or bell structure having a convex cross-sectional shape, but an embodiment according to present disclosure is not limited thereto.

The convex portion 122 may include an inclined portion having a curved shape between a bottom portion and the top portion. The inclined portion of the convex portion 122 may form or configure the concave portion 121. For example, the inclined portion of the convex portion 122 may be an inclined surface or a curved portion. The inclined portion of the convex portion 122 according to an embodiment may have a cross-sectional structure having Gaussian curve. In this case, the inclined portion of the convex portion 122 may have a tangent slope which increases progressively from the bottom portion to the top portion, and then decreases progressively.

The light emitting device layer E may be disposed over the light extraction portion 120 overlapping with the light emission area EA. The light emitting device layer E may be configured to emit the light toward the substrate 110 according to a bottom emission type, but an embodiment according to present disclosure is not limited thereto. The light emitting device layer E according to an embodiment may include a first electrode 114, an organic light emitting layer 116, and a cathode electrode 117.

The light emitting device layer E may generate light responsive to current supplied thereto through the pixel circuit and thus, may emit the light. The concave portion 121 or the convex portion 122 of the light extraction portion 120 changes the traveling path of the light emitted from the organic light emitting layer 116 to the light emitting surface (or substrate 110), to thereby increase the external extraction efficiency of the light emitted from the organic light emitting layer 116. For example, the convex portion 122 prevents or reduces degradation of the light extraction efficiency caused by the light which is trapped in the light emitting device layer E by repeating total reflection between the first electrode 114 and the cathode electrode 117 of the light emitting device layer E without traveling to the light emitting surface. Accordingly, in the light emitting display device according to an embodiment of the present disclosure, the light extraction efficiency of light emitted from the light emitting device layer E may be enhanced.

The light emitting display apparatus 100 according to an example embodiment of the present disclosure may include a flat portion 130 connected to the light extraction portion 120 and surrounding the light extraction portion 120. The flat portion 130 according to an example may be provided on an upper surface of the overcoat layer 113. Accordingly, as shown in FIG. 3, the flat portion 130 may be labeled with a drawing symbol of 113a. The flat portion 130 is disposed above the plurality of concave portions 121, for example, closer to the opposite substrate 200.

As shown in FIG. 3, the light emitting display apparatus 100 according to an example embodiment of the present disclosure may include the bank 115 spaced apart from the light extraction portion 120 and disposed on the flat portion 130. The bank 115 may include an upper surface disposed closest to the opposite substrate 200, and an inclined surface extending from the upper surface and connecting to a light blocking portion 140. As shown in FIG. 3, when the inclined surface of the bank 115 is disposed on the flat portion 130, the taper angle of the inclined surface of the bank 115 with respect to the upper surface of the substrate 110 may be lowered compared to when the inclined surface of the bank is disposed in a groove such as the concave portion. Accordingly, the light emitting display apparatus 100 according to an example embodiment of the present disclosure may be prevented from thinning the thickness of the cathode electrode 117 formed on the bank 115, thus the breakage of the cathode electrode 117 by an external force such as an impact or the like may be prevented, thereby improving reliability.

In the light emitting display apparatus 100 according to an example embodiment of the present disclosure, the bank 115 may include organic materials. When the bank 115 includes organic materials, the organic materials may be filled into the grooves such as the concave portion 121 to form a taper angle of the inclined surface of the bank 115 to be sharp. Therefore, the light emitting display apparatus 100 according to an example embodiment of the present description is provided such that the bank 115 is spaced apart from the light extraction portion 120 and is disposed on the flat portion 130, so that even if the bank 115 includes organic materials, the taper angle of the inclined surface of the bank 115 may decrease, and thus the disconnection of the cathode electrode 117 by an external force may be prevented.

Referring again to FIG. 3, in the light emitting display apparatus 100 according to an example embodiment of the present disclosure, the first electrode 114 is disposed on the light extraction portion 120 and the flat portion 130 and may be partially covered by the bank 115. For example, as shown in FIG. 3, the first electrode 114 may be disposed on the upper surface of the entire light extraction portion 120 and extend to a portion of the flat portion 130 that is below the bank 115. Thus, the edges of the first electrode 114 may be covered by the bank 115.

In the light emitting display apparatus 100 according to an example embodiment of the present disclosure, the organic light emitting layer 116 may be disposed on the first electrode 114 and the bank 115 (or on the light extraction portion 120 and the flat portion 130, and on the bank 115). Since the organic light emitting layer 116 includes organic materials, the thickness of the organic light emitting layer 116 may be thinner on the inclined surface of the first electrode 114 (or the light extraction portion 120) (or the portion where the first electrode 114 bends at the light extraction portion 120), and on the upper side of the convex portion 122, as shown in FIG. 3. In contrast, the thickness of the organic light emitting layer 116 may be thicker at the portion disposed closest to the substrate 110 in each of the plurality of concave portions 121, and on the flat portion 130. The portion disposed closest to the substrate 110 in each of the plurality of concave portions 121 may be represented as the closest concave portion with respect to the substrate 110. As a result, the organic light emitting layer 116 may be disposed along the profile of a layer contacting below the organic light emitting layer 116, for example, the light blocking portion 140 and/or the first electrode 114, which may result in different thicknesses depending on where the organic light emitting layer 116 is formed.

If the thickness of the organic light emitting layer is different, the interval (or optical distance) between the first electrode and the cathode electrode may be different, resulting in a different magnitude of the electric field, which may cause an abnormal color defect. However, in the light emitting display apparatus 100 according to an example embodiment of the present disclosure, color abnormality defects may be prevented through the light blocking portion 140 even if the thickness of the organic light emitting layer 116 varies depending on the location. Color abnormality defects may refer to a color change depending on the viewing angle, that is, the color coordinates of the light shift depending on the viewing angle. Color abnormality defects are closely related to the color temperature, for example, a decrease in color temperature may shift the color coordinates towards red, and an increase in color temperature may shift the color coordinates towards blue. As a result, the light emitting display apparatus may be free of color abnormality defects if there is no change in the position of the color coordinates depending on the viewing angle. The light emitting display apparatus 100 according to an example embodiment of the present disclosure may minimize or prevent fluctuations of color coordinates according to a viewing angle through the light blocking portion 140, so that color abnormality defects may be prevented.

As shown in FIG. 3, the light emitting display apparatus 100 according to an example embodiment of the present disclosure may include the light blocking portion 140 disposed in at least a portion of the area between the organic light emitting layer 116 and the first electrode 114. For example, the light blocking portion 140 may be disposed on a portion of the flat portion 130 adjacent to the light extraction portion 120. However, not limited thereto, the light blocking portion 140 may be disposed on a portion of the flat portion 130 and a portion of the light extraction portion 120. In this case, the light blocking portion 140 disposed on a portion of the flat portion 130 and the light blocking portion 140 disposed on a portion of the light extraction portion 120 may be connected as one.

The light blocking portion 140 is to block transmission of light emitted from the organic light emitting layer 116 on the flat portion 130, or to prevent the organic light emitting layer 116 on the flat portion 130 from emitting light. For example, the light blocking portion 140 may block light emitted by the organic light emitting layer 116 on the flat portion 130 from emitting toward the substrate 110. Alternatively, the light blocking portion 140 may be oxidized and insulated by an oxygen plasma process to prevent the formation of an electric field with the cathode electrode 117, thereby preventing the emission of the organic light emitting layer 116. Thus, as shown in FIG. 2, the light blocking portion 140 in plan may be provided as a structure surrounding the light extraction portion 120. The light blocking portion 140 according to one example may be provided to include reflective materials, thereby blocking transmission of light emitted from the organic light emitting layer 116 on the flat portion 130. The reflective materials according to one example may include MoTi.

On the other hand, the light blocking portion 140 may be formed by the following process. First, the first electrode 114 and the light blocking portion 140 and the bank 115 may be sequentially stacked on the overcoat layer 113. In this case, the light blocking portion 140 may be formed with the thickness that reduces or blocks the transmission of light emitted from the organic light emitting layer 116. Next, secondarily, the bank 115 on the light extraction portion 120 may be photopatterned. Then, thirdly, the light blocking portion 140 on the light extraction portion 120 may be etched away using the bank 115 as a mask. Then, fourthly, the bank 115 on the flat portion 130 may be ashed such that the light blocking portion 140 on the flat portion 130 is exposed, partially uncovered by the bank 115. Thus, the light emitting display apparatus 100 according to an example embodiment of the present disclosure may be provided with the light blocking portion 140 disposed between the flat portion 130 and the organic light emitting layer 116 and not partially covered by the bank 115. Further, as shown in FIG. 3, the light blocking portion 140 may be disposed below the organic light emitting layer 116 and between the bank 115 and the light extraction portion 120.

Since the light emitting display apparatus 100 according to an example embodiment of the present disclosure is provided with the light blocking portion 140 disposed on at least a portion between the organic light emitting layer 116 and the first electrode 114 (or on the flat portion 130 connected to the light extraction portion 120), color abnormality defects due to the thickness difference (or optical distance difference) between the organic light emitting layer 116 on the light extraction portion 120 (or on the convex portion 122) and the organic light emitting layer 116 on the flat portion 130 may be prevented. Furthermore, the light emitting display apparatus 100 according to an example embodiment of the present disclosure may be provided with a structure in which the light blocking portion 140 surrounds the light extraction portion 120, therefore prevention of color abnormality defects of each of the plurality of sub-pixels SPs may be maximized.

Further, the light emitting display apparatus 100 according to the present disclosure may be provided such that each of the plurality of sub-pixels SPs includes the light blocking portion 140 and the light extraction portion 120. Thus, light extraction efficiency of light emitted from the light emitting device layer E may be improved while color abnormality defects are prevented.

Furthermore, the light emitting display apparatus 100 according to the present disclosure may be provided such that each of the plurality of sub-pixels SPs includes the light extraction portion 120, thus have the same light extraction efficiency or even better light extraction efficiency at a lower power compared to a light emitting display apparatus without the light extraction portion, thereby reducing overall power consumption.

On the other hand, in the light emitting display apparatus 100 according to an example embodiment of the present disclosure, the light blocking portion 140 is provided to include MoTi, so that the organic light emitting layer 116 on the light blocking portion 140 may also be emitted by the formation of an electric field between the light blocking portion 140 and the cathode electrode 117. Thus, in the light emitting display apparatus 100 according to an example embodiment of the present disclosure, the light emission area EA may be an area including the light extraction portion 120 and the light blocking portion 140 that are not covered by the bank 115. For example, in the light emitting display apparatus 100 according to an example embodiment of the present disclosure, the light emission area EA may be provided to have a first width W1, as shown in FIG. 3.

Hereinafter, with reference to FIG. 4, a structure of each of the plurality of subpixels SP will be described in detail.

As shown in FIG. 4, a light emitting display apparatus 100 according to an example embodiment of the present disclosure may include a buffer layer BL, a circuit element layer 111, a thin film transistor 112, the overcoat layer 113, the first electrode 114, the bank 115, the organic light emitting layer 116, the cathode electrode 117, a filling layer 118, and the color filter CF.

In more detail, each of the subpixels SP according to an example embodiment may include the circuit element layer 111 provided on an upper surface of the buffer layer BL, including a gate insulating layer 111a, an interlayer insulating layer 111b and a passivation layer 111c, an overcoat layer 113 provided on the circuit element layer 111, the color filter CF between the overcoat layer 113 and the passivation layer 111c, the first electrode 114 provided on the overcoat layer 113, a bank 115 covering an edge of the first electrode 114, an organic light emitting layer 116 on the first electrode 114 and the bank 115, the cathode electrode 117 on the organic light emitting layer 116, and the filling layer 118 on the cathode electrode 117.

The thin film transistor 112 for driving the subpixel SP may be disposed on the circuit element layer 111. The circuit element layer 111 may be expressed as the term of an inorganic film layer. The buffer layer BL may be included in the circuit element layer 111 together with the gate insulating layer 111a, the interlayer insulating layer 111b and the passivation layer 111c. The first electrode 114, the organic light emitting layer 116 and the cathode electrode 117 may be included in the light emitting device layer E.

The buffer layer BL may be formed between the substrate 110 and the gate insulating layer 111a to protect the thin film transistor 112. The buffer layer BL may be disposed on the entire surface (or front surface) of the substrate 110. The pixel power line EVDD for pixel driving may be disposed between the buffer layer BL and the substrate 110. The pixel power line EVDD may be disposed below the bank 115 while being spaced apart from the thin film transistor 112. The reference line RL may also be disposed between the buffer layer BL and the substrate 110. The reference line RL may be disposed in the non-light emission area NEA that does not overlap with the light emission area EA. The buffer layer BL may serve to block diffusion of a material contained in the substrate 110 into a transistor layer during a high temperature process of a manufacturing process of the thin film transistor. Optionally, the buffer layer BL may be omitted in some cases.

The thin film transistor 112 (or a drive transistor) according to an example may include an active layer 112a, a gate electrode 112b, a source electrode 112c, and a drain electrode 112d.

The active layer 112a may include a channel area, a drain area, and a source area, which are formed in a thin film transistor area of a circuit area of the subpixel SP. The drain area and the source area may be spaced apart from each other with the channel area interposed therebetween.

The active layer 112a may be formed of a semiconductor material based on any one of amorphous silicon, polycrystalline silicon, oxide, and organic material.

The gate insulating layer 111a may be formed on the channel area of the active layer 112a. As an example, the gate insulating layer 111a may be formed in an island shape only on the channel area of the active layer 112a, or may be formed on an entire front surface of the substrate 110 or the buffer layer BL, which includes the active layer 112a.

The gate electrode 112b may be formed on the gate insulating layer 111a to overlap the channel area of the active layer 112a.

The interlayer insulating layer 111b may be formed on the gate electrode 112b and the drain area and the source area of the active layer 112a. As shown in FIG. 4, the interlayer insulating layer 111b may be formed in an entire light emission area, in which light is emitted to the subpixel SP. However, embodiments of the present disclosure are not limited thereto, the interlayer insulating layer 111b may be patterned between the drain electrode 112d and the gate electrode 112b and drain region of the active layer 112a and may be arranged in an island shape, and moreover, may be patterned between the source electrode 112c and the gate electrode 112b and source region of the active layer 112a and may be arranged in an island shape.

The source electrode 112c may be electrically connected to the source area of the active layer 112a through a source contact hole provided in the interlayer insulating layer 111b overlapped with the source area of the active layer 112a. The drain electrode 112d may be electrically connected to the drain area of the active layer 112a through a drain contact hole provided in the interlayer insulating layer 111b overlapped with the drain area of the active layer 112a.

The drain electrode 112d and the source electrode 112c may be made of the same metal material. For example, each of the drain electrode 112d and the source electrode 112c may be made of a single metal layer, a single layer of an alloy or a multi-layer of two or more layers, which is the same as or different from that of the gate electrode.

In addition, the circuit area may further include first and second switching thin film transistors disposed together with the thin film transistor 112, and a capacitor. Since each of the first and second switching thin film transistors is provided on the circuit area of the subpixel SP to have the same structure as that of the thin film transistor 112, its description will be omitted. The capacitor (not shown) may be provided in an overlap area between the gate electrode 112b and the source electrode 112c of the thin film transistor 112, which overlap each other with the interlayer insulating layer 111b interposed therebetween.

Additionally, in order to prevent a threshold voltage of the thin film transistor provided in a pixel area from being shifted by light, the display panel or the substrate 110 may further include a light shielding layer (not shown) provided below the active layer 112a of at least one of the thin film transistor 112, the first switching thin film transistor, and the second switching thin film transistor. The light shielding layer may be disposed between the substrate 110 and the active layer 112a to shield light incident on the active layer 112a through the substrate 110, thereby minimizing a change in the threshold voltage of the transistor due to external light. Also, since the light shielding layer is provided between the substrate 110 and the active layer 112a, the thin film transistor may be prevented from being seen by a user.

The passivation layer 111c may be provided on the substrate 110 to cover the pixel area. The passivation layer 111c covers a drain electrode 112d, a source electrode 112c and a gate electrode 112b of the thin film transistor 112, and the buffer layer BL.

Meanwhile, as shown in FIG. 4, the pixel power lines EVDD may be disposed to overlap the bank 115 in the third direction (Z-axis direction). Also, the reference line RL may be disposed to overlap the bank 115 in the third direction (Z-axis direction). The passivation layer 111c may be formed throughout entire of the circuit area CA and the light emission area EA. Such passivation layer 111c may be omitted.

The overcoat layer 113 may be disposed on the substrate 110 to cover the passivation layer 111c. When the passivation layer 111c is omitted, the overcoat layer 113 may be disposed on the substrate 110 to cover the circuit area (or thin film transistor 112). The overcoat layer 113 may be formed in the circuit area CA in which the thin film transistor 112 is disposed and the light emission area EA. In addition, the overcoat layer 113 may be formed in the other non-display area NDA except a pad area PA of the non-display area NDA and the entire display area DA. For example, the overcoat layer 113 may include an extension portion (or an enlarged portion) extended or enlarged from the display area DA to the other non-display area NDA except the pad area PA. Therefore, the overcoat layer 113 may have a size relatively wider than that of the display area DA.

The overcoat layer 113 according to one example may be formed to have a relatively thick thickness, thereby providing a flat surface on the display area DA and the non-display area NDA. For example, the overcoat layer 113 may be made of an organic material such as photo acryl, benzocyclobutene, polyimide and fluorine resin.

The color filter CF may be disposed between the overcoat layer 113 and the passivation layer 111c. Alternatively, the color filter CF may be disposed between the light extraction portion 120 and the substrate 110. As described above, the white sub-pixel SP2 may not be provided with the color filter because the organic light emitting layer 116 emits white light. On the other hand, in the red sub-pixel SP1, a first color filter CF1 (or red color filter CF1) may be provided between the overcoat layer 113 and the passivation layer 111c. In the blue sub-pixel SP3, a second color filter (or blue color filter) may be provided between the overcoat layer 113 and the passivation layer 111c. In the green sub-pixel SP4, a third color filter (or a green color filter) may be provided between the overcoat layer 113 and the passivation layer 111c.

The color filter CF according to one example may convert white light from each of the plurality of sub-pixels SP into different colored light. Accordingly, the color filter CF may have a width (or size) equal to or larger than the light emission area EA. Thus, as shown in FIG. 3, the color filter CF may be disposed overlapping the light extraction portion 120, a portion of the flat portion 130, and a portion of the bank 115.

Meanwhile, the light extraction portion 120 and the flat portion 130 may be disposed on the upper surface of the overcoat layer 113. The light extraction portion 120, according to one example, may include the plurality of concave portions 121, and the convex portion 122 (or the plurality of convex portion 122) disposed around each of the plurality of concave portions 121. The flat portion 130, according to one example, may be connected to the light extraction portion 120 and disposed to surround the light extraction portion 120. The first electrode 114 may be disposed on the light extraction portion 120 and the flat portion 130.

The first electrode 114, according to one example, may be formed on the overcoat layer 113 (or a portion of the flat portion 130 and the light extraction portion 120). The first electrode 114 may be connected to a drain electrode or a source electrode of the thin film transistor 112 via contact holes through the overcoat layer 113 and the passivation layer 111c. An edge of one side portion of the first electrode 114 may be covered by the bank 115. The first electrode 114 may include at least one of a transparent metal material, a translucent metal material.

Because the display apparatus 100 according to an embodiment of the present disclosure is configured as the bottom emission type, the first electrode 114 may be formed of a transparent conductive material (or TCO), such as indium tin oxide (ITO) or indium zinc oxide (IZO) capable of transmitting light, or a semi-transmissive conductive material such as magnesium (Mg), silver (Ag), or an alloy of Mg and Ag. The first electrode 114 may be an anode electrode or a pixel electrode.

The bank 115 may be disposed on one side of a light emission area EA of each of the plurality of sub-pixels SPs, which is an area where no light is emitted. For example, the bank 115 may be disposed in a non-light emission area NEA. The bank 115 may cover an edge of the first electrode 114. Accordingly, the bank 115 may prevent the cathode electrode 117 from contacting the first electrode 114 at the edge of the first electrode 114. The exposed portion of the first electrode 114 not covered by the bank 115 may include a light emitting portion (or light emission area EA).

In the light emitting display apparatus 100 according to an example embodiment of the present disclosure, the light blocking portion 140 is disposed on the first electrode 114 in the third direction (Z-axis direction) and may be disposed between the light extraction portion 120 and the bank 115 in the second direction (X-axis direction). Here, the light blocking portion 140 may be disposed to extend between the bank 115 and the flat portion 130 (or the first electrode 114) such that it partially overlaps the bank 115. Thus, as shown in FIG. 3, the light blocking portion 140 may be disposed to extend from an end of the light extraction portion 120 to a bottom of a portion of the bank 115. Therefore, as shown in FIG. 3, the light blocking portion 140 may be provided to overlap each of the light emission area EA and the non-light emission area NEA.

After the bank 115 is formed to cover the edge of the first electrode 114 and the edge of the light blocking portion 140, the organic light emitting layer 116 may be formed to cover the first electrode 114, the light blocking portion 140, and the bank 115, that are on the light extraction portion 120. Thus, in the non-light emission area NEA, the bank 115 may be provided between the first electrode 114 (or the light blocking portion 140) and the organic light emitting layer 116. Such the bank 115 may be expressed in terms of a pixel-defining membrane. The bank 115 according to one example may include organic materials.

As shown in FIG. 3, the light blocking portion 140 is disposed to extend from the light emission area EA to a portion of the non-light emission area NEA, so that the bank 115 may overlap with a portion of the first electrode 114 and a portion of the light blocking portions 140, respectively.

The organic light emitting layer 116 may be formed on the first electrode 114, the light blocking portion 140, and the bank 115, that are on the light extraction portion 120. The organic light emitting layer 116 according to one example may be disposed in a light emission area EA and a non-light emission area NEA. Since the organic light emitting layer 116 is disposed between the first electrode 114 and the cathode electrode 117 on the light extraction portion 120, when a voltage is applied to each of the first electrode 114 and the cathode electrode 117, an electric field is formed between the first electrode 114 and the cathode electrode 117, which may cause the organic light emitting layer 116 to emit light. Further, the organic light emitting layer 116 may be provided between the light blocking portion 140 on the flat portion 130 and the cathode electrode 117. Since the light blocking portion 140 includes MoTi, an electric field may be formed between the light blocking portion 140 and the cathode electrode 117 on the flat portion 130, which may cause the organic light emitting layer 116 on the flat portion 130 to emit.

The light emitting display apparatus 100 according to an example embodiment of the present disclosure is provided such that the light blocking portion 140 disposed on the flat portion 130 does not transmit light emitted from the organic light emitting layer 116, so that color abnormality defects between the organic light emitting layer 116 emitting on the flat portion 130 and the organic light emitting layer 116 emitting on the light extraction portion 120 may be prevented. For example, a user may watch a video through the light emitted by the organic light emitting layer 116 toward the substrate 110, and the light emitted by the organic light emitting layer 116 on the flat portion 130 is blocked by the light blocking portion 140, so that the user may only see the light emitted by the organic light emitting layer 116 on the light extraction portion 120. Therefore, the light emitting display apparatus 100 according to an example embodiment of the present disclosure can prevent color abnormality defects even if the organic light emitting layer 116 on the light extraction portion 120 and the organic light emitting layer 116 on the flat portion 130 are provided with different thicknesses. As a result, in the light emitting display apparatus 100 according to an example embodiment of the present disclosure, each of the plurality of sub-pixels SPs is disposed on the light extraction portion 120 and the flat portion 130 and includes the first electrode 114 (or disposed between the organic light emitting layer 116 and the light extraction portion 120) partially covered by the bank 115, the first electrode 114 is disposed to extend between the light blocking portion 140 and the flat portion 130, and the light blocking portion 140 may have structural features disposed between the first electrode 114 and the organic light emitting layer 116. Furthermore, the light emitting display apparatus 100 according to an example embodiment of the present disclosure may have a structural feature in which the light blocking portion 140 is disposed to extend between the bank 115 and the flat portion 130 such that the light blocking portion 140 partially overlaps the bank 115, thus the light blocking portion 140 is partially disposed between the bank 115 and the first electrode 114.

On the other hand, the organic light emitting layer 116 may be formed as a common layer on a plurality of sub-pixels SPs and the bank 115.

The organic light emitting layer 116 according to an embodiment may be provided to emit white light. The organic light emitting layer 116 may include a plurality of stacks which emit lights of different colors. For example, the organic light emitting layer 116 may include a first stack, a second stack, and a charge generating layer (CGL) provided between the first stack and the second stack. The light emitting layer may be provided to emit the white light, and thus, each of the plurality of subpixels SP may include a color filter CF suitable for a corresponding color.

The first stack may be provided on the first electrode 114 and may be implemented a structure where a hole injection layer (HIL), a hole transport layer (HTL), an emission layer (EML(B)), and an electron transport layer (ETL) are sequentially stacked.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant.

The second stack may be provided on the first stack and may be implemented in a structure where a hole transport layer (HTL), a yellow-green (YG) emission layer (EML(YG)), and an electron injection layer (EIL) are sequentially stacked.

In the display apparatus 100 according to an embodiment of the present disclosure, because the organic light emitting layer 116 is provided as a common layer, the first stack, the charge generating layer, and the second stack may be arranged all over the plurality of subpixels SP. The organic light emitting layer 116, according to another example, may be provided in a three-stacked structure or a four-stacked structure, depending on the number of stacks stacked.

The cathode electrode 117 may be formed on the organic light emitting layer 116. The cathode electrodes 117 may be disposed in the light emission area EA and the non-light emission area NEA. The cathode electrode 117 according to one example may include a metal material. The cathode electrode 117 may reflect the light emitted from the organic light emitting layer 116 in the plurality of subpixels SP toward the lower surface of the substrate 110. Therefore, the display apparatus 100 according to an example embodiment of the present disclosure may be implemented as a bottom emission type display apparatus.

The display apparatus 100 according to an example embodiment of the present disclosure is a bottom emission type that reflects light emitted from the light emitting layer 116 toward the substrate 110, and thus the cathode electrode 117 may be made of a metal material having high reflectance. The cathode electrode 117 according to one example may be formed of a metal material having high reflectance such as a stacked structure (Ti/Al/Ti) of aluminum and titanium, a stacked structure (ITO/Al/ITO) of aluminum and ITO, an Ag alloy, and a stacked structure (ITO/Ag alloy/ITO) of Ag alloy and ITO. The Ag alloy may be an alloy such as silver (Ag), palladium (Pd) and copper (Cu). The cathode electrode 117 may be expressed as terms such as a second electrode, a cathode electrode, and a counter electrode.

The filling layer 118 is formed on the cathode electrode 117. The filling layer 118 prevents oxygen or moisture from penetrating into the organic light emitting layer 116 and the cathode electrode 117. For that, the filling layer 118 may be provided to include a getter capable of absorbing oxygen or moisture. Alternatively, the filling layer 118 may include a plurality of layers including at least one inorganic film and at least one organic film.

Meanwhile, as shown in FIG. 4, the filling layer 118 may be disposed not only in the light emission area EA but also in the non-light emission area NEA. The filling layer 118 may be disposed between the cathode electrode 117 and an opposite substrate 200.

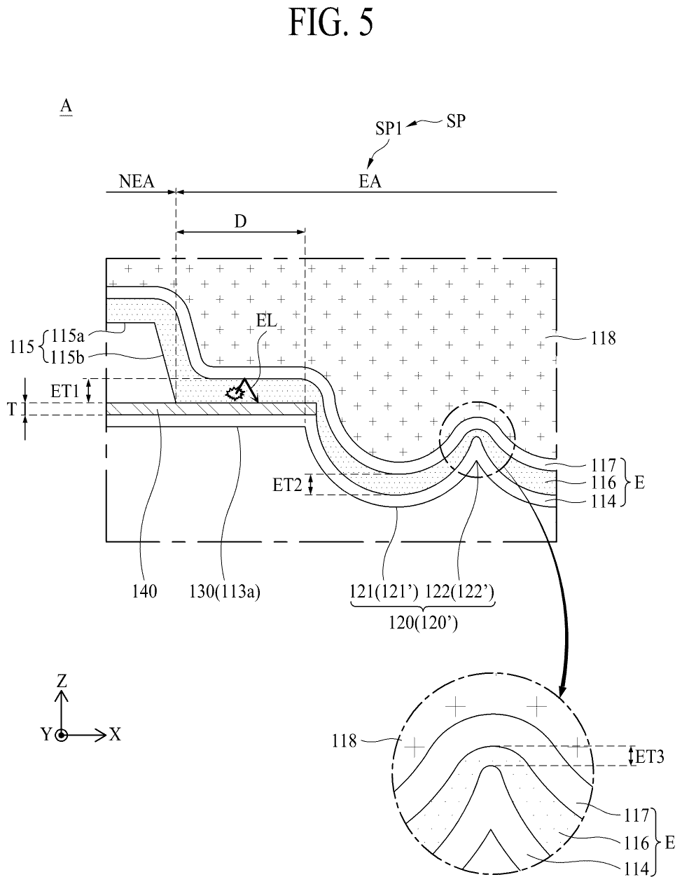

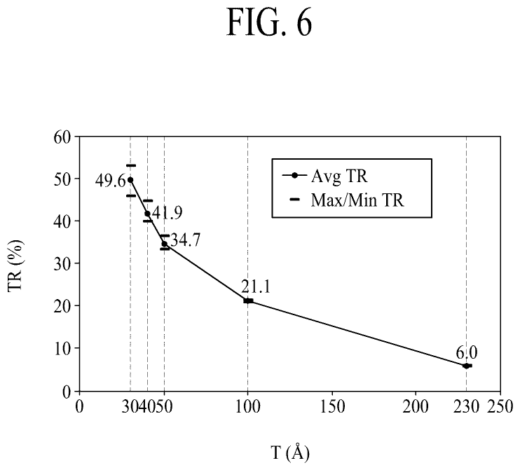

Hereinafter, with reference to FIGS. 5 and 6, the light extraction portion 120 and the light blocking portion 140 of the light emitting display apparatus 100 according to an example embodiment of the present disclosure will be described in more detail.

FIG. 5 is a schematic enlarged cross-sectional view of portion A shown in FIG. 3, and FIG. 6 is a graph illustrating the transmittance of the light blocking portion as a function of the thickness of the light blocking portion of a light emitting display apparatus according to an example embodiment of the present disclosure.

Referring now to FIG. 5, in the light emitting display apparatus 100 according to an example embodiment of the present disclosure, the bank 115 may include an upper surface 115a disposed uppermost, and an inclined surface 115b connected to the upper surface 115a and in contact with the upper surface of the light blocking portion 140. As shown in FIG. 5, in the light emitting display apparatus 100 according to an example embodiment of the present disclosure, the bank 115 may be spaced apart from the light extraction portion 120 to reduce the taper angle of the inclined surface 115b of the bank 115 (i.e., the angle between the lower surface of the bank 115 and the inclined surface 115b of the bank 115). For example, the inclined surface 115b of the bank 115 may be spaced apart from the light extraction portion 120 (or an outermost light extraction portion 120′) by a first distance D. The outermost light extraction portion 120′ is meant the light extraction portion disposed outermost from light extraction portion 120 and may include an outermost concave portion 121′ and an outermost convex portion 122′.

The outermost concave portion 121′, according to one example, may be included in the plurality of concave portions 121 and connected to the flat portion 130. The outermost convex portion 122′ is included in the convex portion 122 and may be disposed only on one side of the outermost concave portion 121′. Since the outermost light extraction portion 120′ is connected to the flat portion 130, the pointed outermost convex portion 122′ may be disposed only on one side of the outermost light extraction portion 120′ (or the outermost concave portion 121′). Alternatively, one side of the outermost concave portion 121′ may refer to the area between the outermost concave portion 121′ and another concave portion disposed adjacent to the outermost concave portion 121′.

As shown in FIG. 5, the thickness ET1 of the organic light emitting layer 116 disposed on the light blocking portion 140 may be thicker than the thickness ET3 of the organic light emitting layer 116 disposed on the convex portion 122 of the light extraction portion 120 (or the convex portion 122′ of the outermost light extraction portion 120′). That is, the thickness ET3 of the organic light emitting layer 116 disposed on the convex portion 122 (or the convex portion 122′ of the light extraction portion 120′) may be thinner than the thickness ET1 of the organic light emitting layer 116 disposed on the light blocking portion 140. When the thickness of the organic light emitting layer 116 is thinner, the interval (or optical distance) between the first electrode 114 and the cathode electrode 117 is small, thus the electric field is formed intensely, therefore more light is emitted compared to when the thickness of the organic light emitting layer 116 is thicker. In other words, when the thickness of the organic light emitting layer 116 is thinner, the luminance (or color temperature) may be high. Therefore, light emission may occur mainly from the organic light emitting layer 116 on the convex portion 122 among the organic light emitting layer 116 on the light extraction portion 120.

In contrast, the thickness ET1 of the organic light emitting layer 116 disposed on the flat portion 130 is thicker than the thickness ET3 of the organic light emitting layer 116 disposed on the convex portion 122 of the light extraction portion 120 (or the convex portion 122′ of the outermost light extraction portion 120′), so the luminance (or color temperature) of the organic light emitting layer 116 disposed on the flat portion 130 may be low. Therefore, in the case of a general light emitting display apparatus, since the luminance (or color temperature) of the organic light emitting layer disposed on the flat portion and the organic light emitting layer disposed on the convex portion are different, color abnormality defects depending on the viewing angle may occur. However, the light emitting display apparatus 100 according to an example embodiment of the present disclosure is provided with the light blocking portion 140 below the organic light emitting layer 116 disposed on the flat portion 130, so that even if the thickness of the organic light emitting layer 116 on the flat portion 130 and the thickness of the organic light emitting layer 116 on the convex portion 122 (or the outermost convex portion 122′) are different, the light blocking portion 140 blocks the transmission of light emitted from the organic light emitting layer 116, and thus color abnormality defects may be prevented, as shown in FIG. 5.

On the other hand, as shown in FIG. 5, the thickness ET1 of the organic light emitting layer 116 disposed on the light blocking portion 140 may be equal to or thicker than the thickness ET2 of the organic light emitting layer 116 disposed on each of the plurality of concave portions 121. Here, the thickness ET2 of the organic light emitting layer 116 disposed in each of the plurality of concave portions 121 may refer to the thickness of the organic light emitting layer 116 disposed on the concave portion, which is disposed closest to the substrate 110, among each of the plurality of concave portions 121. Since the plurality of concave portions 121 are provided in the shape of grooves, it may be difficult to deposit the material included in the organic light emitting layer 116 to each of the plurality of concave portions 121 when depositing the organic light emitting layer 116. Accordingly, the thickness ET1 of the organic light emitting layer 116 disposed on the light blocking portion 140 may be equal to as or thicker than the thickness ET2 of the organic light emitting layer 116 disposed on each of the plurality of concave portions 121. Therefore, the light emitted from the organic light emitting layer 116 disposed on the light blocking portion 140 may have a similar luminance (or color temperature) or a slightly lower luminance with an insignificant difference than the light emitted from the organic light emitting layer 116 disposed on the concave portion 121 closest to the substrate 110 in each of the plurality of concave portions 121.

In the light emitting display apparatus 100 according to an example embodiment of the present disclosure, the light blocking portion 140 may be provided with the thickness T that reduces or blocks the transmission of light emitted from the organic light emitting layer 116 on the flat portion 130.

FIG. 6 is a graph illustrating the light transmittance of a light blocking portion with respect to the thickness of a light blocking portion of the light emitting display apparatus according to an example embodiment of the present disclosure, the horizontal axis indicates the thickness T of the light blocking portion 140, and the perpendicular axis indicates a light transmittance TR. As shown in FIG. 6, it can be seen that as the thickness T of the light blocking portion 140 becomes thicker, the light transmittance TR becomes lower. That is, the graph of the light transmittance with respect to the thickness of the light blocking portion 140 is downward to the right. For example, when the thickness T of the light blocking portion 140 is 30 Å, the average transmittance Avg TR may be about 49.6%, when the thickness T of the light blocking portion 140 is 100 Å, the average transmittance Avg TR may be about 21.1%, and when the thickness T of the light blocking portion 140 is 230 Å, the average transmittance Avg TR may be about 6%. The average transmittance Avg TR according to one example is a value between the maximum and minimum transmittance (Max/Min TR). Thus, the light emitting display apparatus 100 according to an example embodiment of the present disclosure may be provided that the thickness T of the light blocking portion 140 is thick, so that light emitted from the organic light emitting layer 116 on the light blocking portion 140 may not penetrate the light blocking portion 140 thereby preventing color abnormality defects.

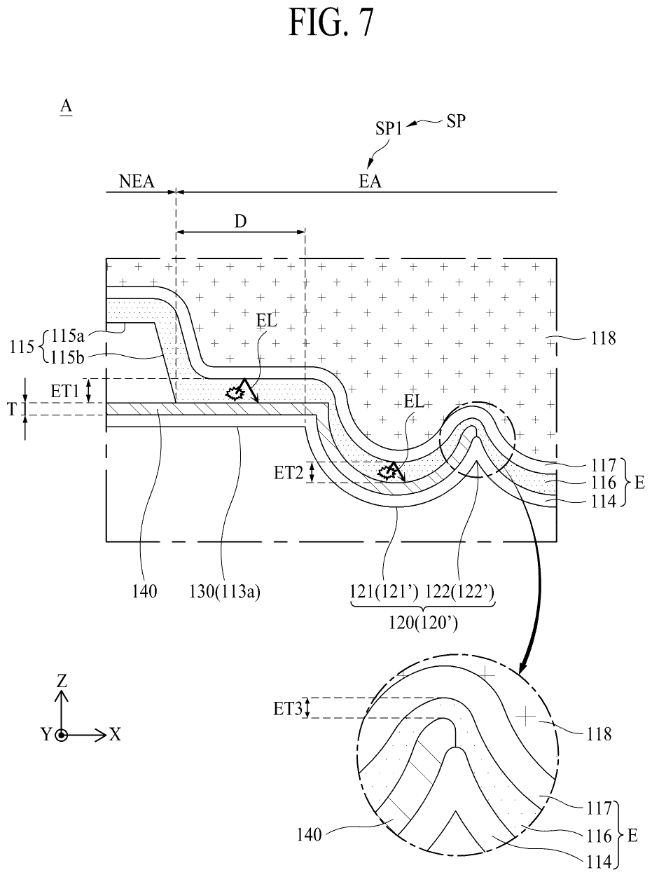

FIG. 7 is an illustration of a modified example of FIG. 5.

In the case of the light emitting display apparatus according to FIG. 5 described above, since the light blocking portion 140 is disposed on the flat portion 130 and the thickness T of the light blocking portion 140 is thick, the transmission of light emitted from the organic light emitting layer 116 on the light blocking portion 140 is reduced or blocked by the light blocking portion 140, thereby preventing color abnormality defects due to the viewing angle.

In contrast, in the case of the light emitting display apparatus according to FIG. 7, the light blocking portion 140 may be disposed to extend from a portion of the flat portion 130 to the outermost concave portion 121′ and the outermost convex portion 122′. In other words, in the case of the light emitting display apparatus according to FIG. 7, the light blocking portion 140 may be disposed to extend from a portion of the flat portion 130 to the outermost light extraction portion 120′. Thus, in the case of the light emitting display apparatus according to FIG. 7, light emitted from the organic light emitting layer 116 disposed on a portion of the flat portion 130 and the outermost light extraction portion 120′ is blocked by the light blocking portion 140 and cannot be directed toward the substrate 110. Therefore, in the light emitting display apparatus 100 according to FIG. 7, the transmission of light emitted from the organic light emitting layer 116 on the flat portion 130 and the outermost light extraction portion 120′ is reduced or blocked by the light blocking portion 140 disposed from the flat portion 130 to the outermost light extraction portion 120′, thereby preventing color abnormality defects due to the viewing angle.

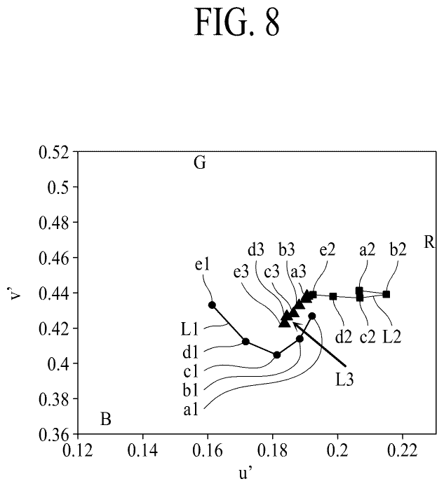

FIG. 8 is a graph illustrating the color coordinates of a light emitting display apparatus according to an example embodiment of the present disclosure compared to color coordinates of a light emitting display apparatus according to a modified example and a comparison example.

As shown in FIG. 8, each of the horizontal axis and the perpendicular axis indicates color coordinates. L1 indicates color coordinates of light emitted from an organic light emitting layer of a light emitting display apparatus according to a comparative example without the light blocking portion 140, L2 indicates color coordinates of light emitted from the organic light emitting layer of a light emitting display apparatus according to an example embodiment of the present disclosure (or a light emitting display apparatus according to FIG. 5), and L3 indicates color coordinates of light emitted from the organic light emitting layer of the light emitting display apparatus according to FIG. 7.

As shown in FIG. 8, it can be seen that each of L1, L2, and L3 all have their color coordinates shifted to the horizontal axis u′. In contrast, it can be seen that L2 and L3 have smaller color coordinate shifts along the perpendicular axis v′ compared to L1. In particular, it can be seen that L2 has almost no shift in the perpendicular axis v′. Little fluctuation in the perpendicular axis v′ may mean that there is little fluctuation of the color coordinates according to the viewing angle. This may mean that there are few color abnormality defects.

More specifically, it can be seen that L1 of FIG. 8 has color coordinate shifts of a1, b1, c1, d1, and e1. a1 indicates the color coordinates when the viewing angle is 0 degrees, b1 indicates the color coordinates when the viewing angle is 15 degrees, c1 indicates the color coordinates when the viewing angle is 30 degrees, d1 indicates the color coordinates when the viewing angle is 45 degrees, and e1 indicates the color coordinates when the viewing angle is 60 degrees. In the case of a1, the color coordinates are located on the red side, and the more the viewing angle increases to c1, the more the graph may shift significantly to the left and downward, causing the color coordinates to shift to the blue side. Also, as the viewing angle from c1 to e1 increases, the graph may shift significantly left and upward and the color coordinates may shift toward the green side. Thus, the light emitting display apparatus according to the comparative example without the light blocking portion may cause the color coordinates (or color temperatures) to shift significantly toward red, blue, and green sequentially depending on the viewing angle, resulting in an abnormal color defect.

On the other hand, L2 in FIG. 8 shows that there is a variation in the color coordinates of a2, b2, c2, d2, and e2. a2 indicates the color coordinates when the viewing angle is 0 degrees, b2 indicates the color coordinates when the viewing angle is 15 degrees, c2 indicates the color coordinates when the viewing angle is 30 degrees, d2 indicates the color coordinates when the viewing angle is 45 degrees, and e2 indicates the color coordinates when the viewing angle is 60 degrees. As the viewing angle increases from a2 to b2, the color coordinates are shifted almost horizontally only to the right, which can shift toward red, and as the viewing angle increases from b2 to e2, the graph is shifted almost horizontally only to the left. This may only mean that the luminance (or color temperature) of the red shifts, but may not mean that a color abnormality occurs. Therefore, since the light emitting display apparatus 100 according to an example embodiment of the present disclosure with the light blocking portion 140 only shifts (or shifts the color coordinates of the horizontal axis u′) the color coordinates (or color temperature) of red depending on the viewing angle, an abnormal color defect may be prevented.

On the other hand, it can be seen that L3 in FIG. 8 has color coordinates shifts of a3, b3, c3, d3, and e3. a3 indicates the color coordinates when the viewing angle is 0 degrees, b3 indicates the color coordinates when the viewing angle is 15 degrees, c3 indicates the color coordinates when the viewing angle is 30 degrees, d3 indicates the color coordinates when the viewing angle is 45 degrees, and e3 indicates the color coordinates when the viewing angle is 60 degrees. It can be seen that as the viewing angle increases from a3 to e3, the graph turns downward to the left, and the color coordinates shift from red to blue. However, it can be seen that L3 has a smaller shift of color coordinates compared to L1. Therefore, the light emitting display apparatus 100 according to FIG. 7, in which the light blocking portion 140 extends not only to the flat portion 130 but also to the outermost light extraction portion 120′, has a smaller shift of the color coordinates depending on the viewing angle compared to the light emitting display apparatus according to the comparative example without the light blocking portion, and thus, color abnormality defects may be prevented.

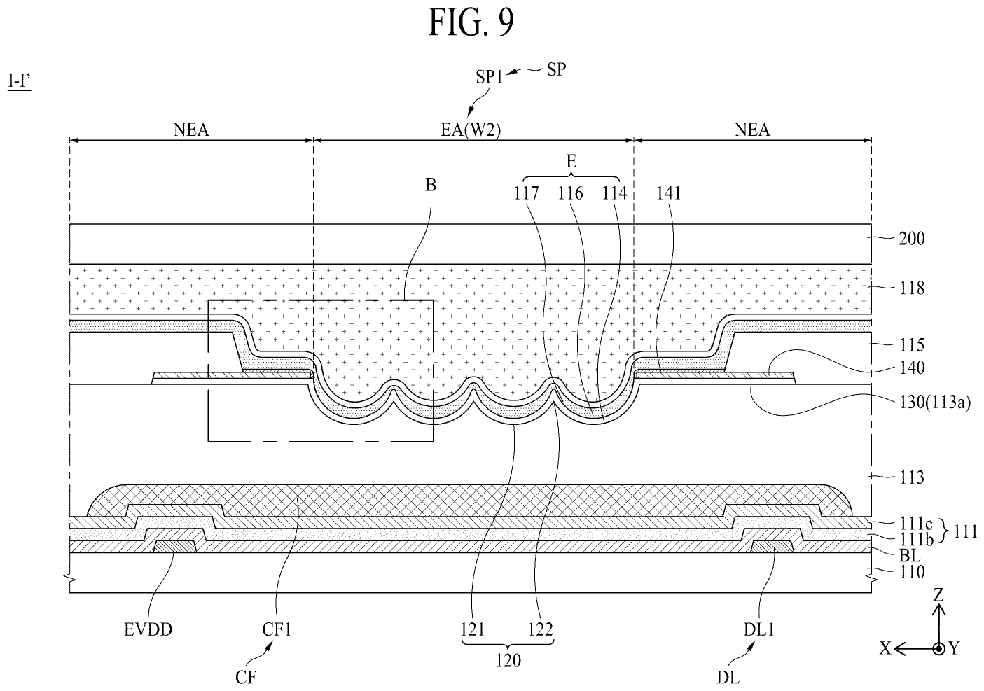

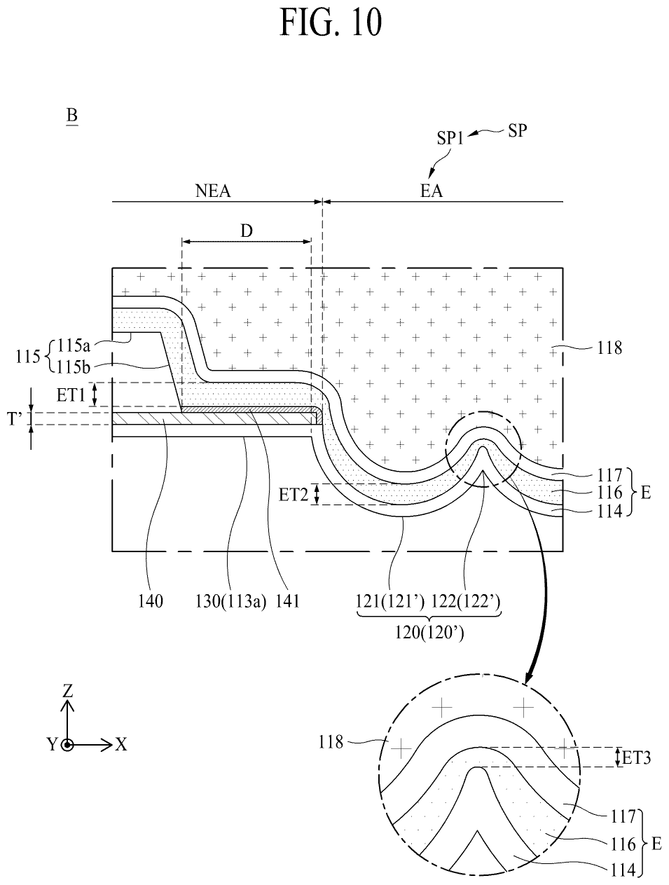

FIG. 9 is a schematic cross-sectional view of a light emitting display apparatus according to another example embodiment of the present disclosure, and FIG. 10 is a schematic enlarged cross-sectional view of portion B shown in FIG. 9.

As shown in FIG. 9, the light emitting display apparatus 100 according to another example embodiment of the present disclosure is the same as the light emitting display apparatus according to FIG. 1 described above, except that the configuration of the oxide film 141 is added. Therefore, the same drawing symbols have been assigned to the same configuration, and only the different configuration will be described hereinafter.

In the light emitting display apparatus according to FIG. 1 described above, the light blocking portion 140 is provided with the thickness T that reduces or blocks the transmission of light emitted from the organic light emitting layer 116 on the flat portion 130, thus the light emitted from the organic light emitting layer 116 on the light blocking portion 140 does not penetrate the light blocking portion 140, thereby preventing abnormal color defect even if the thickness of the organic light emitting layer 116 on the light blocking portion 140 and the thickness of the organic light emitting layer 116 on the light extraction portion 120 (or the convex portion 122) are different.

In contrast, the display device according to FIG. 9 may include an oxide film 141 disposed between the light blocking portion 140 and the organic light emitting layer 116. In one example, the oxide film 141 may be disposed to partially cover the light blocking portion 140. For example, as shown in FIG. 10, the oxide film 141 may cover a portion of the upper surface of the light blocking portion 140 that is not covered by the bank 115, and a side of the light blocking portion 140. The oxide film 141 according to one example may be a metal oxide film in which metal materials are oxidized. For example, the metal oxide film may comprise TiO₂. Thus, in the case of the light emitting display apparatus according to FIG. 9, the organic light emitting layer 116 disposed on the oxide film 141 may not emit light. Therefore, the light emitting display apparatus 100 according to another embodiment of the present disclosure is provided that the organic light emitting layer 116 on the oxide film 141 does not emit light, thereby preventing abnormal color defect even if the thickness of the organic light emitting layer 116 on the oxide film 141 (or the light blocking portion 140) and the thickness of the organic light emitting layer 116 on the light extraction portion 120 (or the convex portion 122) are different.

On the other hand, the light emitting display apparatus 100 according to other embodiments of the present disclosure is provided that the organic light emitting layer 116 disposed on the oxide film 141 (or the light blocking portion 140) does not emit light, such that the light emission area EA may have structural feature provided with a second width W2 narrower than the first width W1 of the light emitting display apparatus according to FIG. 1. In other words, the light emitting display apparatus 100 according to other embodiments of the present disclosure may have an exposed portion (or light emission area (EA)) of the first electrode 114 that is not covered by each of the bank 115 and the oxide film 141. The light emitting display apparatus 100 according to other embodiments of the present disclosure may be more effective to prevent color abnormality defects depending on the viewing angle, as the reduction in luminous efficiency is insignificant even if the light emission area EA is narrowed.

Furthermore, the light emitting display apparatus 100 according to other embodiments of the present disclosure may be provided that the organic light emitting layer 116 disposed on the oxide film 141 (or the light blocking portion 140) does not emit light, the thickness T′ of the light blocking portion 140 may be thinner than the thickness T of the light blocking portion 140 of the light emitting display apparatus according to FIG. 1. However, without being limited thereto, in order to increase the light blocking effect, the thickness T′ of the light blocking portion 140 of the light emitting display apparatus 100 according to other embodiments of the present disclosure may be provided equal to or thicker than the thickness T of the light blocking portion 140 of the light emitting display apparatus according to FIG. 1.

Referring again to FIG. 9, the light emitting display apparatus 100 according to another embodiment of the present disclosure may be disposed such that an oxide film 141 surrounds the light extraction portion 120. The oxide film 141 according to one example may be formed by the following process. First, the first electrode 114, the light blocking portion 140 (or metal materials) and the bank 115 may be sequentially stacked on the overcoat layer 113. In this case, the thickness of the light blocking portion 140 may be formed to the thickness that reduces or blocks the transmission of light emitted from the organic light emitting layer 116. However, without being limited thereto, the light emitting display apparatus 100 according to FIG. 9 may be provided such that the organic light emitting layer 116 disposed on the light blocking portion 140 does not emit light, the thickness of the light blocking portion 140 (or metal materials) may be thinner compared to the light emitting display apparatus according to FIG. 1. Then, secondly, the bank 115 on the light extraction portion 120 may be photopatterned. Then, thirdly, a light blocking portion 140 (or metal materials) on the light extraction portion 120 may be etched and removed using the bank 115 as a mask. Then, fourthly, the bank 115 on the flat portion 130 is ashing so that the light blocking portion 140 (or metal materials) on the flat portion 130 may be exposed without being partially covered by the bank 115. Next, fifthly, O₂ plasma ashing process (or oxidation process) may be performed on the light blocking portion 140 (or metal materials) exposed and not covered by the bank 115, and the oxide film 141 may be formed covering a portion of the upper surface of the light blocking portion 140, and the sides of the light blocking portion 140 (or metal oxide film). In the light emitting display apparatus 100 according to other embodiments of the present disclosure, the oxide film 141 covering the portion of the upper surface portion of the light blocking portion 140, and the side surface of the light blocking portion 140 (or a metal oxide film) may be formed in a self-aligned manner by process oxidizing the light blocking portion 140 (or metal materials) exposed without being covered by the bank 115, thereby being manufactured more easily than the case that separately depositing the oxide film (or insulation film) to cover the light blocking portion.

The light emitting display apparatus 100 according to other embodiments of the present disclosure may have structural features that the oxide film 141 is provided to cover a portion of the upper surface of the exposed light blocking portion 140 not covered by the bank 115, and the side of the light blocking portion 140, thus at least a portion of the oxide film 141 is disposed between the bank 115 and the light extraction portion 120. Furthermore, the light emitting display apparatus 100 according to other embodiments of the present disclosure may have structural features that the oxide film 141 is provided to cover a portion of the upper surface of the exposed light blocking portion 140 not covered by the bank 115, and the side of the light blocking portion 140, thus one surface of the bank 115 is in contact with the light blocking portion 140 and the other surface of the bank 115 is in contact with the oxide film 141. For example, the one surface of the bank 115 may be a lower surface of the bank 115. For example, the other surface of the bank 115 may be the inclined surface 115b of the bank 115.

On the other hand, the light emitting display apparatus 100 according to another example embodiment of the present disclosure is provided that each of the plurality of sub-pixels SP includes the oxide film 141 and the light extraction portion 120, thus abnormal color defect is prevented thereby improving the light extraction efficiency of the light emitted from the light emitting element layer.

Furthermore, the light emitting display apparatus 100 according to other embodiments of the present disclosure is provided with each of the plurality of sub-pixels SP that includes the light extraction portion 120, thus have the same light extraction efficiency or even better light extraction efficiency with lower power compared to the light emitting display apparatus without the light extraction portion 120 in each of the plurality of sub-pixels SP, thereby reducing overall power consumption.

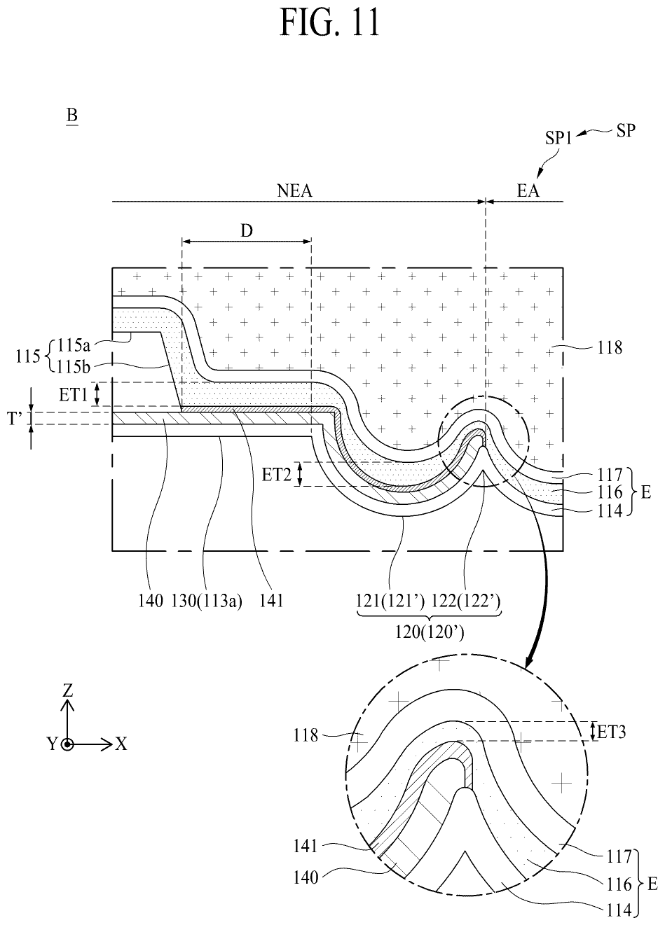

FIG. 11 is an illustration of a modified example of FIG. 10.

In the case of the light emitting display apparatus according to FIG. 10 described above, the oxide film 141 is provided to cover a portion of the upper surface of the exposed light blocking portion 140 not covered by the bank 115, and the side of the light blocking portion 140, thereby preventing the emission of the organic light emitting layer 116 on the oxide film 141, therefore color abnormality defects may be prevented even if the thickness of the organic light emitting layer 116 on the oxide film 141 (or the light blocking portion 140) and the thickness of the organic light emitting layer 116 on the light extraction portion 120 (or the convex portion 122) are different.

In contrast, in the case of the light emitting display apparatus according to FIG. 11, the light blocking portion 140 and the oxide film 141 may be disposed to extend from a portion of the flat portion 130 to the outermost concave portion 121′ and the outermost convex portion 122′. In other words, in the case of the light emitting display apparatus according to FIG. 11, the light blocking portion 140 and the oxide film 141 may be disposed to extend from a portion of the flat portion 130 to the outermost light extraction portion 120′. Here, a portion of the flat portion 130 may refer to the flat portion 130 that is not covered by the bank 115. Thus, in the case of the light emitting display apparatus according to FIG. 11, the organic light emitting layer 116 disposed on the flat portion 130 not covered by the bank 115, and the organic light emitting layer 116 disposed on the outermost light extraction portion 120′ may each not be emitted. Therefore, in the light emitting display apparatus 100 according to FIG. 11, the organic light emitting layer 116, which is disposed on the flat portion 130 and the outermost light extraction portion 120′, does not emit due to the oxide film 141, thus color abnormality defects may be prevented, even if the organic light emitting layer 116 on the oxide film 141 (or the light blocking portion 140) and the organic light emitting layer 116 on the outermost light extraction portion 120′ (or the outermost convex portion 122′) may have different thicknesses.

As a result, in the light emitting display apparatus 100 according to the present disclosure, the bank 115 is disposed on the flat portion 130 spaced apart from the light extraction portion 120, a disconnection of the cathode electrode due to a tapered angle of the inclined surface of the bank 115 may be prevented, thereby improving the lack of reliability.

Furthermore, in the light emitting display apparatus 100 according to an example embodiment of the present disclosure, the light blocking portion 140 is disposed on the flat portion 130 connected to the light extraction portion 120, thus color abnormality defects due to the thickness difference (or optical distance difference) between the organic light emitting layer 116 on the light extraction portion 120 and the organic light emitting layer 116 on the flat portion 130 may be prevented.

Furthermore, the light emitting display apparatus according to the present disclosure may be provided that each of the plurality of sub-pixels SP includes the light blocking portion 140 and the light extraction portion 120, thus color abnormality defects are prevented thereby improving the light extraction efficiency of the light emitted from the light emitting element layer.

Furthermore, the light emitting display apparatus according to the present disclosure may be provided such that each of the plurality of sub-pixels SP includes the light extraction portion 120 and thus may have the same light extraction efficiency or even better light extraction efficiency at a lower power compared to the light emitting display apparatus without the light extraction portion, thereby reducing the overall power consumption.

Furthermore, the light emitting display apparatus 100 according to the present disclosure is provided such that the current pass of the light blocking portion 140, which is disposed on the flat portion 130 without being covered by the bank 115, is blocked through the oxide film 141, thus color abnormality defects due to a difference of the optical distance between the first electrode 114 and the cathode electrode 117 may be improved.

In the light emitting display apparatus according to the present disclosure, the light blocking portion 140 is disposed in at least a portion between the organic light emitting layer 116 and the first electrode 114, thus color abnormality defects due to the thickness difference (or optical distance difference) between the organic light emitting layer 116 on the light extraction portion 120 and the organic light emitting layer 116 on the flat portion 130 may be prevented.

Further, the light emitting display apparatus according to the present disclosure may be provided such that each of the plurality of sub-pixels SP includes the light blocking portion and the light extraction portion, thus light extraction efficiency of light emitted from the light emitting device layer E may be improved through preventing color abnormality defects.

Furthermore, the light emitting display apparatus according to the present disclosure may be provided such that each of the plurality of sub-pixels SP includes the light extraction portion and thus may have the same light extraction efficiency or even better light extraction efficiency at a lower power compared to the light emitting display apparatus without the light extraction portion, thereby reducing the overall power consumption.

The effects to be obtained from the present disclosure are not limited to those mentioned above, and other effects not mentioned will be apparent to one of ordinary skill in the art from the description.

It will be apparent to those skilled in the art that the present disclosure is not limited by the above-described example embodiments and the accompanying drawings, and that various substitutions, modifications, and variations can be made in the present disclosure without departing from the spirit or scope of the disclosures. Therefore, the above example embodiments of the present disclosure are provided for illustrative purposes and are not intended to limit the scope or technical concept of the present disclosure. Therefore, the example embodiments described above are by way of example in all respects and should not be understood as limiting. The protective scope of the present disclosure should be construed based on the following claims and their equivalents, and it is intended that the present disclosure cover all modifications and variations of this disclosure that come within the scope of the claims and their equivalents.

What is claimed is:

1. A light emitting display apparatus, comprising:
a substrate comprising a plurality of pixels having a plurality of sub-pixels;
a light extraction portion disposed on the substrate and located in each of the plurality of sub-pixels;
a flat portion connected to the light extraction portion and surrounding the light extraction portion;
a bank spaced apart from the light extraction portion and disposed on the flat portion;
a first electrode disposed on the light extraction portion and the flat portion and partially covered by the bank;
an organic light emitting layer disposed on the first electrode and the bank; and
a light blocking portion disposed in at least a portion between the organic light emitting layer and the first electrode.

2. The light emitting display apparatus of claim 1, wherein the light blocking portion is disposed below the organic light emitting layer between the bank and the light extraction portion.

3. The light emitting display apparatus of claim 1, wherein the light blocking portion surrounds the light extraction portion.

4. The light emitting display apparatus of claim 2, wherein the light blocking portion is disposed to extend between the bank and the flat portion to partially overlap the bank.

5. The light emitting display apparatus of claim 4, wherein the first electrode is disposed to extend between the light blocking portion and the flat portion.

6. The light emitting display apparatus of claim 5, wherein the light blocking portion is partially disposed between the bank and the first electrode.

7. The light emitting display apparatus of claim 5, wherein the bank overlaps each of a portion of the first electrode and a portion of the light blocking portion.

8. The light emitting display apparatus of claim 1, wherein the bank comprises organic materials.

9. The light emitting display apparatus of claim 1, wherein:
the light extraction portion comprises a plurality of concave portions and a plurality of convex portion disposed around each of the plurality of concave portions; and
the thickness of the organic light emitting layer disposed on each of the plurality of convex portion is thinner than the thickness of the organic light emitting layer disposed on the light blocking portion.

10. The light emitting display apparatus of claim 9, wherein the thickness of the organic light emitting layer disposed on the light blocking portion is equal to or thicker than the thickness of the organic light emitting layer disposed on each of the plurality of concave portions.

11. The light emitting display apparatus of claim 1, further comprising:
a color filter disposed between the light extraction portion and the substrate,
wherein the color filter is disposed to overlap the light extraction portion, a portion of the flat portion, and a portion of the bank.

12. The light emitting display apparatus of claim 1, wherein the light blocking portion comprises reflective materials.

13. The light emitting display apparatus of claim 12, wherein the reflective materials comprise MoTi.

14. The light emitting display apparatus of claim 1, wherein the light blocking portion reduces or blocks transmission of light emitted from the organic light emitting layer on the flat portion.

15. The light emitting display apparatus of claim 9, wherein:
the plurality of concave portions comprise an outermost concave portion connected to the flat portion;
the plurality of convex portion comprises an outermost convex portion on one side of the outermost concave portion; and
the light blocking portion is disposed to extend from a portion of the flat portion to the outermost concave portion and the outermost convex portion.

16. The light emitting display apparatus of claim 1, further comprising:
an oxide film disposed between the light blocking portion and the organic light emitting layer,
wherein the oxide film is disposed to partially cover the light blocking portion.

17. The light emitting display apparatus of claim 16, wherein the oxide film covers a portion of the upper surface of the light blocking portion and a side of the light blocking portion.

18. The light emitting display apparatus of claim 16, wherein the organic light emitting layer disposed on the oxide film does not emit light.

19. The light emitting display apparatus of claim 16, wherein the oxide film is disposed to surround the light extraction portion.

20. The light emitting display apparatus of claim 16, wherein the oxide film is a metal oxide film in which a metal material is oxidized.

21. The light emitting display apparatus of claim 20, wherein the metal oxide comprises TiO₂.

22. The light emitting display apparatus of claim 16, wherein at least a portion of the oxide film is disposed between the bank and the light extraction portion.

23. The light emitting display apparatus of claim 22,
wherein one surface of the bank is in contact with the light blocking portion, and the other surface of the bank is in contact with the oxide film.

24. The light emitting display apparatus of claim 16, wherein:
the light extraction portion comprises a plurality of concave portions and a plurality of convex portion disposed around each of the plurality of concave portions;
the plurality of concave portions comprises an outermost concave portion connected to the flat portion;
the plurality of convex portion comprises an outermost convex portion on one side of the outermost concave portion; and
the light blocking portion and the oxide film are disposed to extend from a portion of the flat portion to the outermost convex portion.

25. The light emitting display apparatus of claim 1, wherein the light blocking portion has a thickness equal to or larger than 230 Å.

26. The light emitting display apparatus of claim 1, wherein the light blocking portion has a thickness between 100 Å and 230 Å.
